(19) United States
(12) Patent Application Publication
(10) Pub. No.: US 2026/0259738 A1
(43) Pub. Date: Sep. 3, 2026

(54) TIME-DIVISION MULTIPLEXED SIMD FUNCTION UNIT

(71) Applicant: Micron Technology, Inc., Boise, ID (US)

(72) Inventors: Tony M. Brewer, Plano, TX (US); Stuart Grime, Seattle, WA (US); David Patrick, Mckinney, TX (US)

(21) Appl. No.: 18/846,638

(22) PCT Filed: Mar. 31, 2023
(86) PCT No.: PCT/US2023/017141

§ 371 Date: Sep. 12, 2024

Related U.S. Application Data
(60) Provisional application No. 63/348,347, filed on Jun. 2, 2022.

(51) Int. Cl. G06F 9/38; G06F 1/10; H03K 19/173

(52) U.S. Cl. CPC G06F 9/3887; G06F 1/10; H03K 19/1737

(57) ABSTRACT

A single-instruction/multiple-data (SIMD) processor uses a function unit that can perform a single operation on multiple data elements. The function unit operates at a higher speed than the rest of the processor, allowing each data element in the SIMD operand to be processed sequentially, using fewer compute resources and avoiding any processing throughput loss. The SIMD processor includes an input register that receives N data elements at the beginning of a clock cycle in a slow clock domain. Each data element of the operand is selected and passed to the function unit on consecutive clock cycles in a fast clock domain. The N results are generated on N successive clock cycles in the fast clock domain and combined to provide multiple results on a single clock cycle in the slow clock domain.

### PRIORITY APPLICATION

This application claims the benefit of priority to U.S. Provisional Application Ser. No. 63/348,347, filed Jun. 2, 2022, which is incorporated herein by reference in its entirety.

### STATEMENT REGARDING GOVERNMENT SUPPORT

This invention was made with Government support under Agreement No. N00014-21-9-0001. The U.S. Government has certain rights in the invention.

As used in this Statement Regarding Government Support, “invention” refers to the subject matter in whole or in part in one or more claims set forth below, or as may be submitted later based on the subject matter of the present specification.

### TECHNICAL FIELD

Embodiments of the disclosure relate generally to operations by processing elements to handle single-instruction/multiple-data (SIMD) commands using a time-division multiplexed SIMD functional unit.

### BACKGROUND

In SIMD processing, a single instruction is received along with multiple data values to be used to perform the instruction. For example, a single “add” instruction may be received along with four pairs of operands, causing four additions to be performed. Since the instruction is only sent once, the instruction overhead is reduced, making processing more efficient.

### BRIEF DESCRIPTION OF THE SEVERAL VIEWS OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

To easily identify the discussion of any particular element or act, the most significant digit or digits in a reference number refer to the figure number in which that clement is first introduced.

FIG. 1 illustrates examples of SIMD instructions, according to an embodiment.

FIGS. 2-3 illustrate generally an example of a hardware design to implement a time-division multiplexed SIMD function unit, according to an embodiment.

FIGS. 4-7 illustrate generally a timing diagram for components of the hardware design of FIGS. 2-3, according to an embodiment.

FIG. 8 is a flow chart showing operations of a method performed by a circuit in performing time-division multiplexed SIMD functions, in accordance with some embodiments of the present disclosure.

FIG. 9 illustrates a block diagram of an example machine with which, in which, or by which any one or more of the techniques (e.g., methodologies) discussed herein can be implemented.

### DETAILED DESCRIPTION

A SIMD processor uses an execution function unit that can perform an operation on multiple data elements in parallel. This parallelism provides greater data processing throughput than a single instruction, single data (SISD) processor, but the improved performance comes at a cost. The SIMD function unit resources, such as multipliers and ALUs, are replicated to concurrently process the multiple data elements in the function unit input operand. This replication adds chip area and design complexity to the processor design.

As described herein, the function unit operates at a higher speed than the rest of the processor, allowing each data element in the SIMD operand to be processed sequentially, using fewer compute resources and avoiding any processing throughput loss. The function unit frequency to processor frequency ratio is greater than or equal to the number of data elements in the operand, to maintain the same performance.

The SIMD processor includes an input register that receives N data elements at the beginning of a clock cycle in a slow clock domain. Each data element of the operand is selected and passed to the function unit on consecutive clock cycles in a fast clock domain. This is accomplished using a multiplexer and a modulo-N counter. The function unit operates in the fast clock domain. The fast clock frequency is N times the slow clock frequency.

The function unit includes X pipe stages. After a data element is processed by the X pipe stages, the result is written to an output register. The N results are generated on N successive clock cycles in the fast clock domain.

The results are passed through Y pipe stages of alignment registers and written into output registers, one fast clock cycle after another as enabled by a modulo-N counter and decoder.

After all N data elements of the result have been received in the output registers, the data elements are driven in parallel to a staging register running in the slow clock domain. The multi-element result is passed to the SIMD processor from the staging register.

By running localized parts of a chip design at a higher frequency than the rest of the design, function unit resources are saved while maintaining the same performance as a SIMD function unit with concurrent processing of data elements. As a result, the size of the physical device may be reduced.

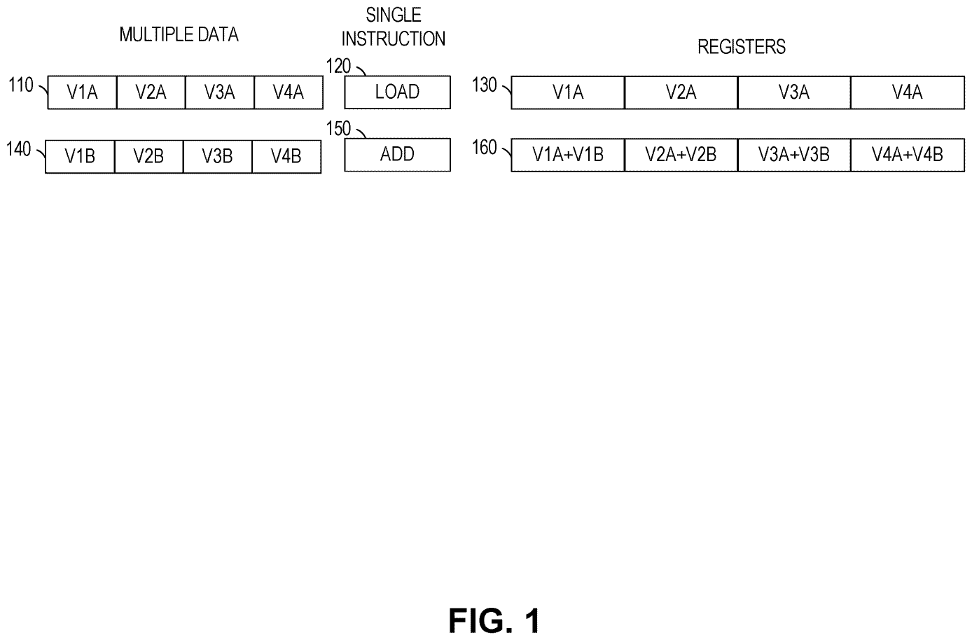

FIG. 1 illustrates examples of SIMD instructions, according to an embodiment. On a first clock cycle, a SIMD processor receives a first single instruction 120 and first multiple data 110. The first single instruction 120 is a load instruction that loads the first multiple data 110 into registers 130. The four data values, V1A, V2A, V3A, and V4A of the first multiple data 110 are loaded into the registers 130 according to the single instruction 120.

On a second clock cycle, the SIMD processor receives a second single instruction 150 and second multiple data 140. The second single instruction 150 is an add instruction that adds the second multiple data 140 to the values in the registers 130. Thus, after execution of the second single instruction 150, the values in the registers are updated as shown in registers 160, which may be the registers 130 at a later time.

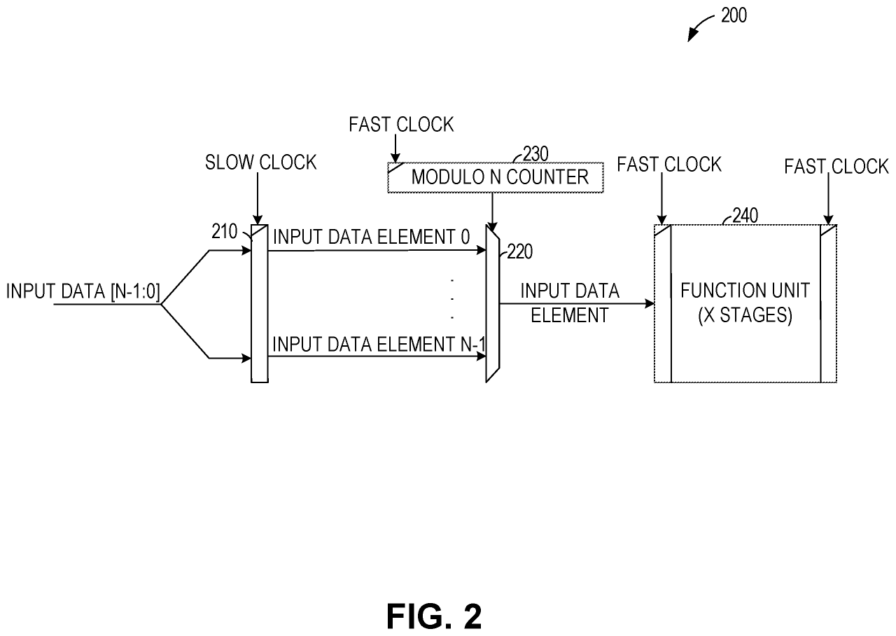

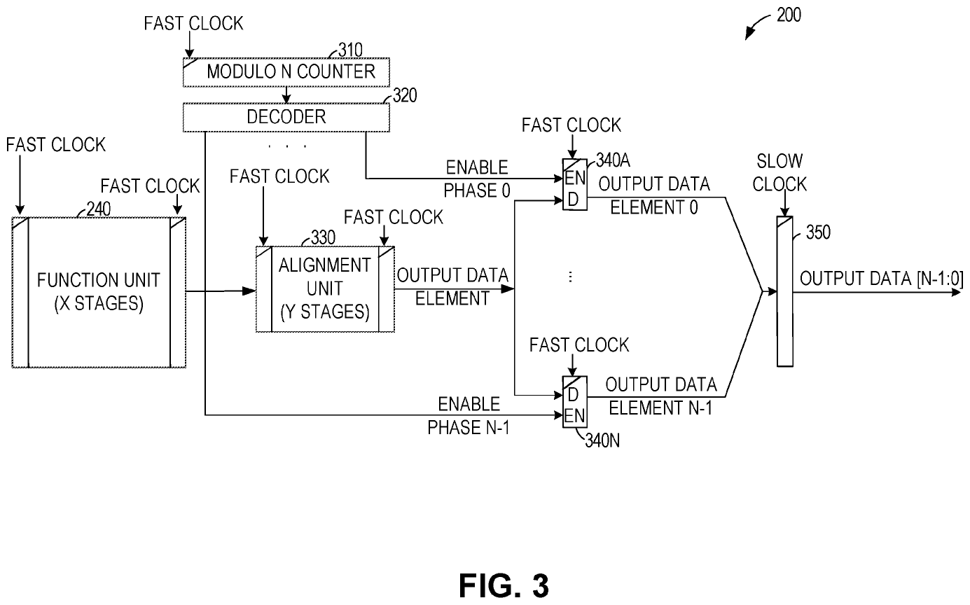

FIGS. 2-3 illustrate generally an example of a hardware design 200 to implement a time-division multiplexed SIMD function unit, according to an embodiment. The hardware design 200 may be implemented in various devices such as a field-programmable gate array (“FPGA”) or an application-specific integrated circuit (“ASIC”).

The hardware design 200 includes an input data interface 210, a multiplexer 220, modulo-N counters 230 and 310, a function unit 240, a decoder 320, an alignment unit 330, latches 340A and 340N, and an output data interface 350. The input data interface 210 and the output data interface 350 operate using a slow clock and the remaining elements operate using a fast clock. The SIMD instruction received comprises N data elements and a single instruction. The fast clock is N times faster than the slow clock. For example, the slow clock may operate at 250 MHz and the fast clock may operate at 1 GHz, which is the clock frequency of the slow clock multiplied by N.

The multiplexer 220 receives the N input data elements as input data values and outputs one of the input values depending on the value of the control signal received. The modulo-N counter 230 provides the control signal to the multiplexer 220. Thus, on N successive fast clock cycles, the N different input values are selected and output by the multiplexer 220.

The function unit 240 receives each different input value and processes it to generate an output. The function unit 240 comprises X stages. As a result, X fast clock cycles pass between the time when an input value is provided to the function unit 240 and a corresponding output is generated. Thus, the first output value is generated at X fast clock cycles after processing of the SIMD command begins and the last output value is generated N−1 fast clock cycles later.

The output of the function unit 240 (using the fast clock) may align with the timing of the output data interface 350 (using the slow clock). For example, if X=1 and N=4, the outputs are completely generated by four fast clock cycles after the SIMD command is received. In this example, the four fast clock cycles are exactly equal to one slow clock cycle. Thus, the output of the function unit 240 may be copied to the output data interface 350 without using the alignment unit 330, ready to be read on the next slow clock cycle.

Alternatively, the output of the function unit 240 may not align with the timing of the output data interface 350. For example, if X=2 and N=4, the last output is generated on the fifth fast clock cycle. Thus, some outputs are ready within the first slow clock cycle and the last one is not ready until the second slow clock cycle. The alignment unit 330 is used to delay the outputs so that they align with the next clock cycle. In this example, a delay of three stages will cause all four outputs to be ready on the second slow clock cycle.

Accordingly, the output of the function unit 240 is provided to the alignment unit 330, which delays each output by a predetermined delay. For example, the alignment unit 330 may comprise Y stages, wherein each stage delays the output by one fast clock cycle. The aligned outputs are then provided to the N latches that store the output data elements (of which two are shown: latches 340A and 340N). The modulo-N counter 310 is provided as an input to the N-output decoder 320. Each of the N outputs of the decoder 320 is provided to a corresponding one of the latches 340A-340N, enabling that latch and causing the corresponding output data to be copied to the output data interface 350. Thus, over N fast clock cycles (one slow clock cycle), the N results are copied to the output data interface 350.

The assertion of the enable signals by the decoder 320 can be thought of as occurring on sequential phases of the slow clock (i.e., phase 0 through phase N−1). The number of alignment staging registers (Y) of the alignment unit 330 is chosen to allow the first data element to arrive in the Output Data Element 0 register at the end of phase N−1. The number of alignment stages may be derived using the following equation: Y=aN−X−3, where “a” is the lowest positive integer that avoids a negative value for Y. In some examples, the value of “a” could be increased further for more alignment stages, to support an architecturally defined pipeline length. This capability may be useful for certain algorithms, such as reduction operations that require function unit results to be fed back to operand inputs after a specific latency.

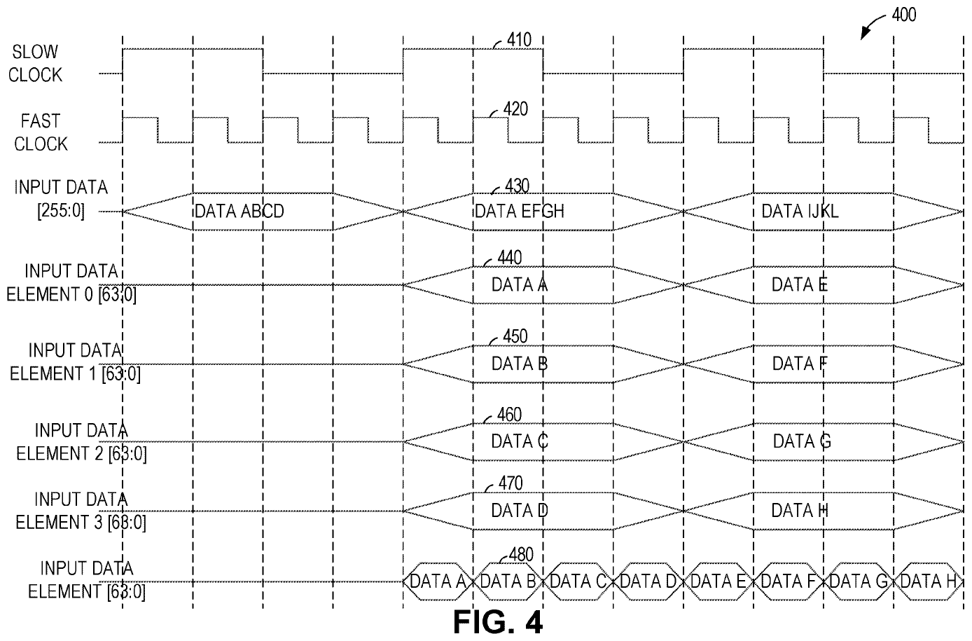

FIGS. 4-7 illustrate generally a timing diagram for components of the hardware design of FIGS. 2-3, according to an embodiment. FIG. 4 illustrates a portion 400 of the timing diagram, comprising three slow clock cycles and twelve fast clock cycles. The portion 400 includes timelines 410, 420, 430, 440, 450, 460, 470, and 480.

The timelines 410 and 420 show the oscillations of the slow clock and the fast clock, respectively. In the examples of FIGS. 4-7, the fast clock is four times faster than the slow clock and the SIMD processor receives four data elements for each instruction. During the first slow clock cycle, the data ABCD is received as a 256-bit input data value, as shown in the timeline 430. During the second slow clock cycle, the input data ABCD is staged as four separate 64-bit input data values, as shown in the timelines 440-470. The separate 64-bit input data values are processed using the modulo-N counter 230 and the multiplexer 220 to provide sequential inputs on the fast clock cycles to the function unit 240, as shown by the timeline 480.

The process of handling input data is repeated by receiving a second 256-bit input value (data EFGH) during the second slow clock cycle and providing those input values sequentially to the function unit 240 during the third slow clock cycle.

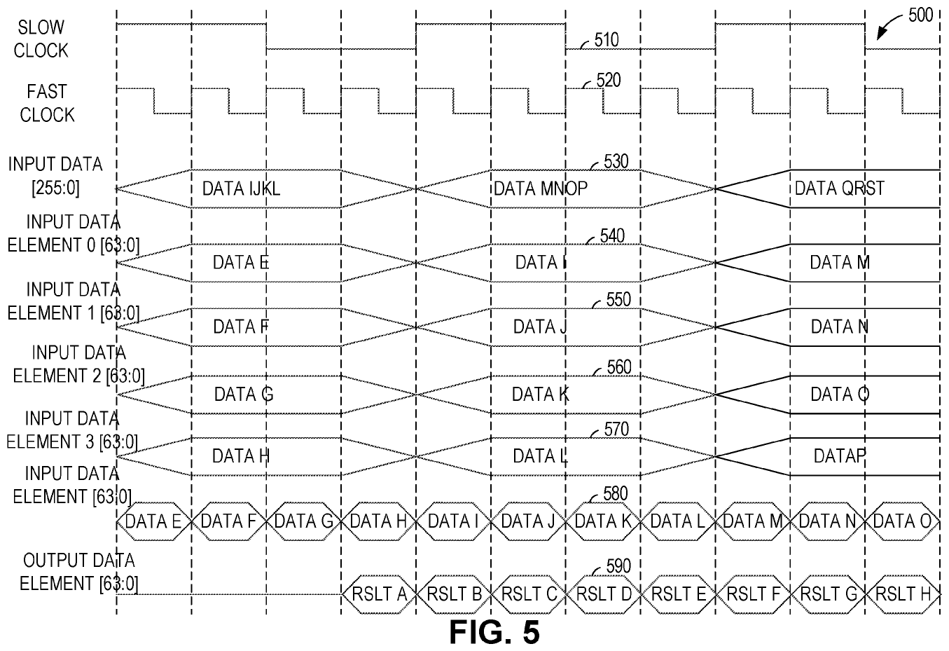

FIG. 5 illustrates a portion 500 of the timing diagram, comprising nearly three slow clock cycles and eleven fast clock cycles. The first slow clock cycle of the portion 500 is the same slow clock cycle as the last slow clock cycle of the portion 400. The portion 500 includes timelines 510, 520, 530, 540, 550, 560, 570, 580, and 590. The timelines 510-580 continue their counterpart timelines 410-480 of the portion 400, with some overlap. The timeline 590 shows 64-bit output data elements generated by the function unit 240.

On successive slow clock cycles, data IJKL, MNOP, and QRST is received as 256-bit input data. On each following slow clock cycle, the 256-bit input data is handled as four 64-bit input values, each of which is successively (on fast clock cycles) provided to the function unit 240.

In the examples of FIGS. 4-7, the first input data, data A, is received by the function unit 240 during the fifth fast clock cycle and the corresponding first output data, result A, is produced during the sixteenth fast clock cycle. Thus, the delay of the function unit 240 is eleven fast clock cycles. Beginning on the sixteenth clock cycle, another result value is provided by the function unit 240 on each fast clock cycle.

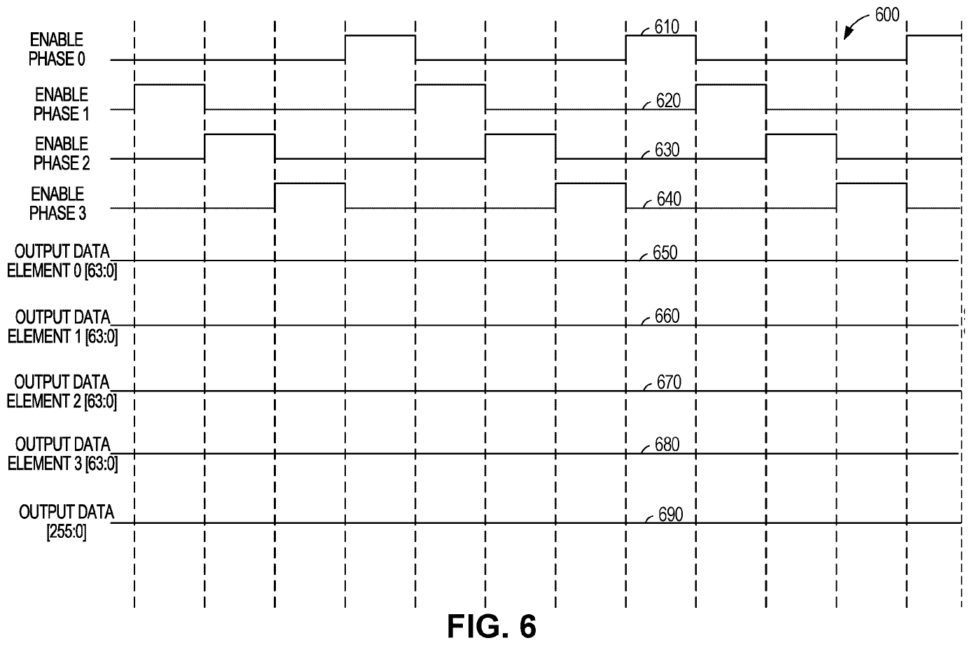

FIG. 6 illustrates a portion 600 of the timing diagram, comprising the same three slow clock cycles and twelve fast clock cycles as the portion 400 of FIG. 4. The portion 600 includes timelines 610, 620, 630, 640, 650, 660, 670, 680, and 690.

The timelines 610-640 show the enable phase 0-3 outputs of the decoder 320 of FIG. 3. The timelines 650-680 show the output data elements 0-3, corresponding to the latches 340A-340N of FIG. 3. Since no output has been generated by the time shown in the portion 600, the output data elements are zero in the portion 600. The timeline 690 shows the output data of the output data interface 350, which is likewise zero in the portion 600.

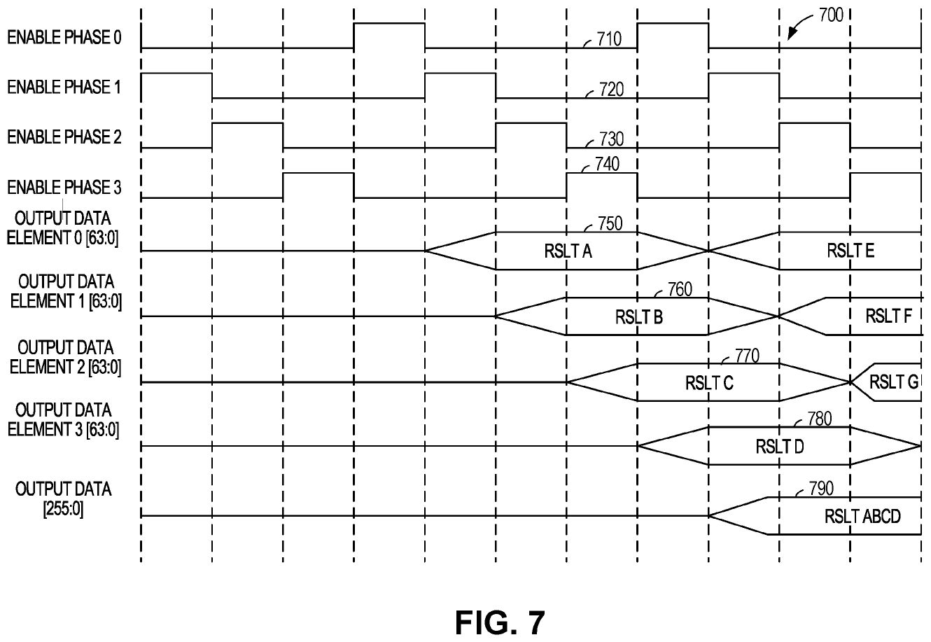

FIG. 7 illustrates a portion 700 of the timing diagram, comprising the same time period as the portion 500 of FIG. 5. The portion 600 includes timelines 710, 720, 730, 740, 750, 760, 770, 780, and 790, each continuing one of the timelines 610-690 of FIG. 6.

The enable phase 0-3 timelines 710-740 show that, on each fast clock cycle, one phase is enabled and that over each slow clock cycle (four fast clock cycles, in the example of FIGS. 4-7), each phase is enabled once. After an enable phase signal is raised, the output data element for that phase receives the next value from the alignment unit 330. The output data element for the phase is maintained until the enable phase signal for the phase is raised again. Thus, after the enable phase 0 signal is raised in the fourth fast clock cycle of the portion 700, the output element 0[63:0] value is set to Result A and the value is held for four fast clock cycles. After the enable phase 1 signal is raised in the fifth fast clock cycle of the portion 700, the output element 1[63:0] value is set to Result B and the value is held for four fast clock cycles. The enable phase 2 and enable phase 3 signals are handled similarly. After all four enable phase 0-3 signals have been received and all four output data elements 0-3 have been latched, the output data [255:0] contains the full SIMD result: Result ABCD.

Thus, the timing diagram of FIGS. 4-7 shows the generation of SIMD results from SIMD inputs using a single function unit 240 and a single alignment unit 330 rather than multiple function units, one for each of the multiple data being processed.

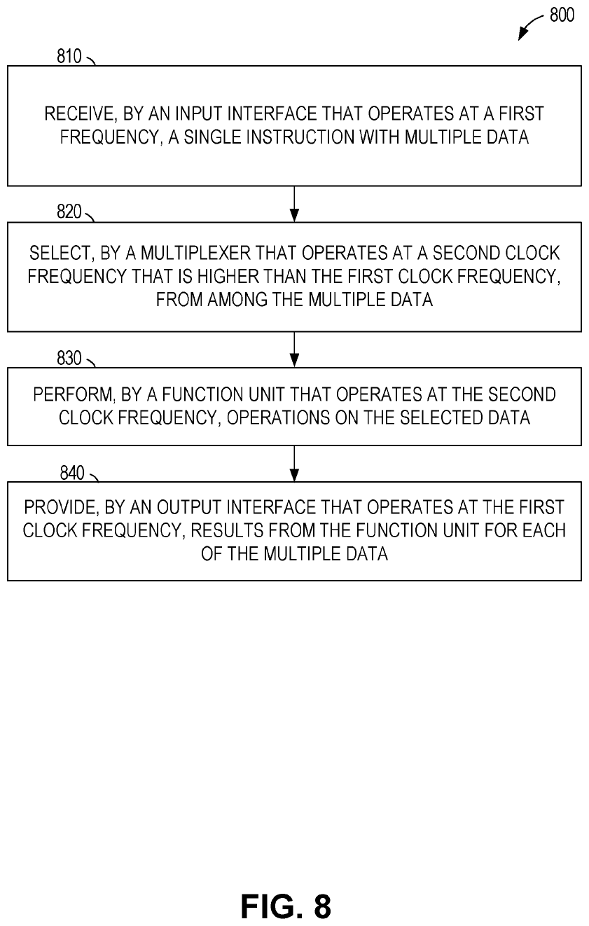

FIG. 8 is a flow chart showing operations of a method 800 performed by a circuit in performing time-division multiplexed SIMD functions, in accordance with some embodiments of the present disclosure. The method 800 includes operations 810, 820, 830, and 840. By way of example and not limitation, the method 800 is described as being performed by a SIMD processor using the hardware design 200 of FIGS. 2-3.

In operation 810, the SIMD processor receives, by or using an input interface that operates at a first frequency, a single instruction with multiple data. For example, the input data interface 210 of FIG. 2, operating at a slow clock frequency, may receive the single instruction 120 or 150 of FIG. 1 with multiple data 110 or 140.

The SIMD processor selects, by or using a multiplexer that operates at a second clock frequency that is higher than the first clock frequency, from among the multiple data in operation 820. For example, the multiplexer 220 of FIG. 2, operating at a fast clock frequency, selects from among the multiple data received by the input data interface 210.

In operation 830, the SIMD processor performs, by or using a function unit that operates at the second clock frequency, operations on the selected data. For example, the function unit 240, operating at the fast clock frequency, performs X operations on each input data element, beginning on sequential fast clock cycles.

The SIMD processor provides, by or using an output interface that operates at the first clock frequency, results from the function unit for each of the multiple data (operation 840). For example, the output data interface 350 of FIG. 3, operating at the slow clock frequency, provides results for each of the multiple data elements.

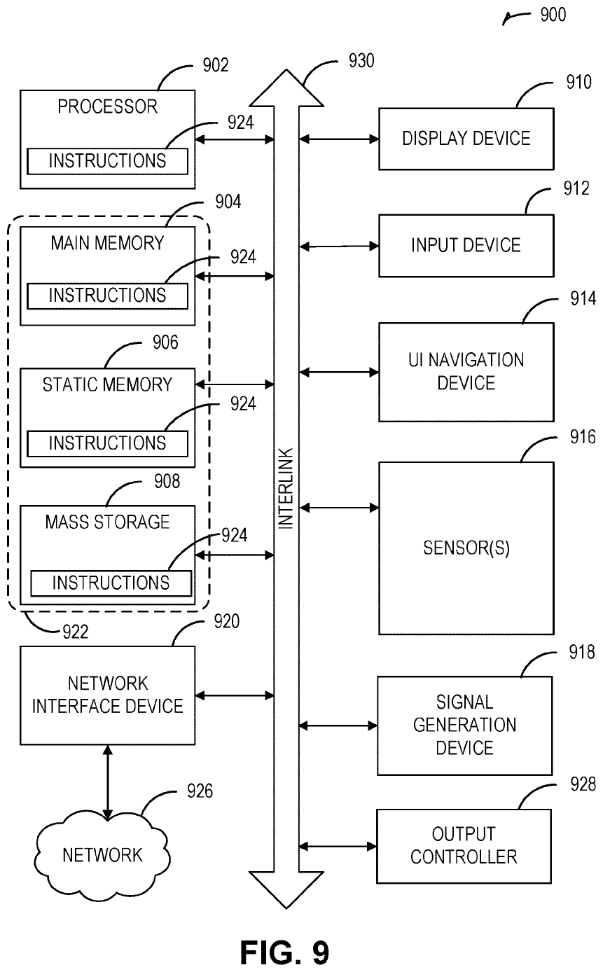

FIG. 9 illustrates a block diagram of an example machine 900 with which, in which, or by which any one or more of the techniques (e.g., methodologies) discussed herein can be implemented. Examples, as described herein, can include, or can operate by, logic or a number of components, or mechanisms in the machine 900. Circuitry (e.g., processing circuitry) is a collection of circuits implemented in tangible entities of the machine 900 that include hardware (e.g., simple circuits, gates, logic, etc.). Circuitry membership can be flexible over time. Circuitries include members that can, alone or in combination, perform specified operations when operating. In an example, hardware of the circuitry can be immutably designed to carry out a specific operation (e.g., hardwired). In an example, the hardware of the circuitry can include variably connected physical components (e.g., execution units, transistors, simple circuits, etc.) including a machine-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine-readable medium elements are part of the circuitry or are communicatively coupled to the other components of the circuitry when the device is operating. In an example, any of the physical components can be used in more than one member of more than one circuitry. For example, under operation, execution units can be used in a first circuit of a first circuitry at one point in time and reused by a second circuit in the first circuitry, or by a third circuit in a second circuitry at a different time. Additional examples of these components with respect to the machine 900.

In alternative embodiments, the machine 900 can operate as a standalone device or can be connected (e.g., networked) to other machines. In a networked deployment, the machine 900 can operate in the capacity of a server machine, a client machine, or both in server-client network environments. In an example, the machine 900 can act as a peer machine in peer-to-peer (P2P) (or other distributed) network environment. The machine 900 can be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations.

The machine 900 (e.g., computer system) can include a hardware processor 902 (e.g., a central processing unit (CPU), a graphics processing unit (GPU), a hardware processor core, or any combination thereof), a main memory 904, a static memory 906 (e.g., memory or storage for firmware, microcode, a basic-input-output (BIOS), unified extensible firmware interface (UEFI), etc.), and mass storage device 908 (e.g., hard drives, tape drives, flash storage, or other block devices) some or all of which can communicate with each other via an interlink 930 (e.g., bus). The machine 900 can further include a display device 910, an alphanumeric input device 912 (e.g., a keyboard), and a user interface (UI) navigation device 914 (e.g., a mouse). In an example, the display device 910, the input device 912, and the UI navigation device 914 can be a touch screen display. The machine 900 can additionally include a signal generation device 918 (e.g., a speaker), a network interface device 920, and one or more sensor(s) 916, such as a global positioning system (GPS) sensor, compass, accelerometer, or other sensor. The machine 900 can include an output controller 928, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the hardware processor 902, the main memory 904, the static memory 906, or the mass storage device 908 can be, or include, a machine-readable media 922 on which is stored one or more sets of data structures or instructions 924 (e.g., software) embodying or used by any one or more of the techniques or functions described herein. The instructions 924 can also reside, completely or at least partially, within any of registers of the hardware processor 902, the main memory 904, the static memory 906, or the mass storage device 908 during execution thereof by the machine 900. In an example, one or any combination of the hardware processor 902, the main memory 904, the static memory 906, or the mass storage device 908 can constitute the machine-readable media 922. While the machine-readable media 922 is illustrated as a single medium, the term “machine-readable medium” can include a single medium or multiple media (e.g., a centralized or distributed database, or associated caches and servers) configured to store the one or more instructions 924.

The term “machine readable medium” can include any medium that is capable of storing, encoding, or carrying instructions for execution by the machine 900 and that cause the machine 900 to perform any one or more of the techniques of the present disclosure, or that is capable of storing, encoding, or carrying data structures used by or associated with such instructions. Non-limiting machine-readable medium examples can include solid-state memories, optical media, magnetic media, and signals (e.g., radio frequency signals, other photon-based signals, sound signals, etc.). In an example, a non-transitory machine-readable medium comprises a machine-readable medium with a plurality of particles having invariant (e.g., rest) mass, and thus are compositions of matter. Accordingly, non-transitory machine-readable media are machine readable media that do not include transitory propagating signals. Specific examples of non-transitory machine-readable media can include: non-volatile memory, such as semiconductor memory devices (e.g., electrically programmable read-only memory (EPROM), electrically erasable programmable read-only memory (EEPROM)) and flash memory devices; magnetic disks, such as internal hard disks and removable disks; magneto-optical disks; and CD-ROM and DVD-ROM disks.

In an example, information stored or otherwise provided on the machine-readable media 922 can be representative of the instructions 924, such as instructions 924 themselves or a format from which the instructions 924 can be derived. This format from which the instructions 924 can be derived can include source code, encoded instructions (e.g., in compressed or encrypted form), packaged instructions (e.g., split into multiple packages), or the like. The information representative of the instructions 924 in the machine-readable media 922 can be processed by processing circuitry into the instructions to implement any of the operations discussed herein. For example, deriving the instructions 924 from the information (e.g., processing by the processing circuitry) can include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 924.

In an example, the derivation of the instructions 924 can include assembly, compilation, or interpretation of the information (e.g., by the processing circuitry) to create the instructions 924 from some intermediate or preprocessed format provided by the machine-readable media 922. The information, when provided in multiple parts, can be combined, unpacked, and modified to create the instructions 924. For example, the information can be in multiple compressed source code packages (or object code, or binary executable code, etc.) on one or several remote servers. The source code packages can be encrypted when in transit over a network and decrypted, uncompressed, assembled (e.g., linked) if necessary, compiled or interpreted (e.g., into a library, stand-alone executable etc.) at a local machine, and executed by the local machine.

The instructions 924 can be further transmitted or received over a communications network 926 using a transmission medium via the network interface device 920 utilizing any one of a number of transfer protocols (e.g., frame relay, internet protocol, transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), plain old telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 920 can include one or more physical jacks (e.g., Ethernet, coaxial, or phone jacks) or one or more antennas to connect to the network 926. In an example, the network interface device 920 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 900, and includes digital or analog communications signals or other intangible medium to facilitate communication of such software. A transmission medium is a machine readable medium.

To better illustrate the methods and apparatuses described herein, a non-limiting set of Example embodiments are set forth below as numerically identified Examples.

Example 1 is a system comprising: an input interface that receives a single instruction with multiple data, the input interface operating at a first clock frequency; a multiplexer that selects from among the multiple data, the multiplexer operating at a second clock frequency that is higher than the first clock frequency; a function unit that operates on the selected data, the function unit operating at the second clock frequency; and an output interface that provides results from the function unit for each of the multiple data, the output interface operating at the first clock frequency.

In Example 2, the subject matter of Example 1, wherein: the multiple data comprise N data elements; and the second clock frequency is N multiplied by the first clock frequency.

In Example 3, the subject matter of Example 2 includes a modulo N counter coupled to the multiplexer and configured to provide a control signal to the multiplexer to control the selection from among the multiple data.

In Example 4, the subject matter of Examples 1-3 includes an alignment unit that: receives an output of the function unit; provides the output of the function unit after a predetermined delay; and operates at the second clock frequency.

In Example 5, the subject matter of Example 4, wherein: the multiple data comprises N data elements; the function unit comprises X stages; the alignment unit comprises Y stages, where Y=aN−X−3 and a is the lowest positive integer that avoids a negative value for Y.

In Example 6, the subject matter of Examples 4-5, wherein: the multiple data comprises N data elements; the function unit comprises X stages; the alignment unit comprises Y stages, where Y=aN−X−3 and a is greater than the lowest positive integer that avoids a negative value for Y.

In Example 7, the subject matter of Examples 4-6 includes multiple output registers that receive output from the alignment unit and provide the output to the output interface, the multiple output registers operating at the second clock frequency.

In Example 8, the subject matter of Example 7, wherein: the multiple data comprises N data elements; and further comprising a modulo N counter connected to a decoder that selects from among the multiple output registers for each output from the alignment unit, the modulo N counter operating at the second clock frequency.

In Example 9, the subject matter of Examples 1-8, wherein the system is part of a field programmable gate array (FPGA).

In Example 10, the subject matter of Examples 1-9, wherein the system is part of an application-specific integrated circuit (ASIC).

Example 11 is a method comprising: receiving, by an input interface that operates at a first clock frequency, a single instruction with multiple data; selecting, by a multiplexer that operates at a second clock frequency that is higher than the first clock frequency, from among the multiple data; performing, by a function unit that operates at the second clock frequency, operations on the selected data; and providing, by an output interface that operates at the first clock frequency, results from the function unit for each of the multiple data.

In Example 12, the subject matter of Example 11, wherein: the multiple data comprise N data elements; and the second clock frequency is N multiplied by the first clock frequency.

In Example 13, the subject matter of Example 12 includes controlling, by a modulo N counter, the selection among the multiple data.

In Example 14, the subject matter of Examples 11-13 includes receiving, by an alignment unit that operates at the second clock frequency, output of the function unit; and providing, by the alignment unit and after a predetermined delay, the output of the function unit.

In Example 15, the subject matter of Example 14, wherein: the multiple data comprises N data elements; the function unit comprises X stages; the alignment unit comprises Y stages, where Y=aN−X−3 and a is the lowest positive integer that avoids a negative value for Y.

In Example 16, the subject matter of Examples 14-15, wherein: the multiple data comprises N data elements; the function unit comprises X stages; the alignment unit comprises Y stages, where Y=aN−X−3 and a is greater than the lowest positive integer that avoids a negative value for Y.

In Example 17, the subject matter of Examples 14-16 includes receiving, by multiple output registers that operate at the second clock frequency, output from the alignment unit; and providing, by the multiple output registers, the output to the output interface.

In Example 18, the subject matter of Example 17, wherein: the multiple data comprises N data elements; and further comprising selecting, by a decoder connected to a modulo N counter, from among the multiple output registers for each output from the alignment unit.

In Example 19, the subject matter of Examples 11-18, wherein the receiving of the single instruction by the input interface comprises receiving the single instruction with a field programmable gate array (FPGA) interface.

In Example 20, the subject matter of Examples 11-19, wherein the receiving of the single instruction by the input interface comprises receiving the single instruction with an application-specific integrated circuit (ASIC) interface.

Example 21 is at least one machine-readable medium including instructions that, when executed by processing circuitry, cause the processing circuitry to perform operations to implement any of Examples 1-20.

Example 22 is an apparatus comprising means to implement any of Examples 1-20.

Example 23 is a system to implement any of Examples 1-20.

Example 24 is a method to implement any of Examples 1-20.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” can include “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” and the like are used merely as labels, and are not intended to impose numerical requirements on their objects.

The above description is intended to be illustrative, and not restrictive. For example, the above-described examples (or one or more aspects thereof) can be used in combination with each other. Other embodiments can be used, such as by one of ordinary skill in the art upon reviewing the above description. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A system comprising:
an input interface that receives a single instruction with multiple data, the input interface operating at a first clock frequency;
a multiplexer that selects from among the multiple data, the multiplexer operating at a second clock frequency that is higher than the first clock frequency;
a function unit that operates on the selected data, the function unit operating at the second clock frequency; and
an output interface that provides results from the function unit for each of the multiple data, the output interface operating at the first clock frequency.

2. The system of claim 1, wherein:
the multiple data comprise N data elements; and
the second clock frequency is N multiplied by the first clock frequency.

3. The system of claim 2, further comprising:
a modulo N counter coupled to the multiplexer and configured to provide a control signal to the multiplexer to control the selection from among the multiple data.

4. The system of claim 1, further comprising:
an alignment unit that:
receives an output of the function unit;
provides the output of the function unit after a predetermined delay; and
operates at the second clock frequency.

5. The system of claim 4, wherein:
the multiple data comprises N data elements;
the function unit comprises X stages;
the alignment unit comprises Y stages, where Y=aN−X−3 and a is the lowest positive integer that avoids a negative value for Y.

6. The system of claim 4, wherein:
the multiple data comprises N data elements;
the function unit comprises X stages;
the alignment unit comprises Y stages, where Y=aN−X−3 and a is greater than the lowest positive integer that avoids a negative value for Y.

7. The system of claim 4, further comprising:
multiple output registers that receive output from the alignment unit and provide the output to the output interface, the multiple output registers operating at the second clock frequency.

8. The system of claim 7, wherein:
the multiple data comprises N data elements; and
further comprising a modulo N counter connected to a decoder that selects from among the multiple output registers for each output from the alignment unit, the modulo N counter operating at the second clock frequency.

9. The system of claim 1, wherein the system is part of a field programmable gate array (FPGA).

10. The system of claim 1, wherein the system is part of an application-specific integrated circuit (ASIC).

11. A method comprising:
receiving, by an input interface that operates at a first clock frequency, a single instruction with multiple data;
selecting, by a multiplexer that operates at a second clock frequency that is higher than the first clock frequency, from among the multiple data;
performing, by a function unit that operates at the second clock frequency, operations on the selected data; and
providing, by an output interface that operates at the first clock frequency, results from the function unit for each of the multiple data.

12. The method of claim 11, wherein:
the multiple data comprise N data elements; and
the second clock frequency is N multiplied by the first clock frequency.

13. The method of claim 12, further comprising:
controlling, by a modulo N counter, the selection among the multiple data.

14. The method of claim 11, further comprising:
receiving, by an alignment unit that operates at the second clock frequency, output of the function unit; and
providing, by the alignment unit and after a predetermined delay, the output of the function unit.

15. The method of claim 14, wherein:
the multiple data comprises N data elements;
the function unit comprises X stages;
the alignment unit comprises Y stages, where Y=aN−X−3 and a is the lowest positive integer that avoids a negative value for Y.

16. The method of claim 14, wherein:
the multiple data comprises N data elements;
the function unit comprises X stages;
the alignment unit comprises Y stages, where Y=aN−X−3 and a is greater than the lowest positive integer that avoids a negative value for Y.

17. The method of claim 14, further comprising:
receiving, by multiple output registers that operate at the second clock frequency, output from the alignment unit; and
providing, by the multiple output registers, the output to the output interface.

18. The method of claim 17, wherein:
the multiple data comprises N data elements; and
further comprising selecting, by a decoder connected to a modulo N counter, from among the multiple output registers for each output from the alignment unit.

19. The method of claim 11, wherein the receiving of the single instruction by the input interface comprises receiving the single instruction with a field programmable gate array (FPGA) interface.

20. The method of claim 11, wherein the receiving of the single instruction by the input interface comprises receiving the single instruction with an application-specific integrated circuit (ASIC) interface.
